(19) United States
(12) Patent Application Publication
(10) Pub. No.: US 2026/0182408 A1
(43) Pub. Date: Jun. 25, 2026

(54) DOUBLE-SIDED INTEGRATED CIRCUIT (IC) PACKAGE WITH BOTTOM IC(s) HAVING BACKSIDE METALLIZATION, AND RELATED FABRICATION METHODS

(71) Applicant: QUALCOMM Incorporated, San Diego, CA (US)

(72) Inventors: Andreas Franz, Vaterstetten (DE); Marc Huesgen, Singapore (SG); Claus Reitlinger, Wolnzach (DE); Anna Katharina Krefft, Haar (DE)

(21) Appl. No.: 18/987,561

(22) Filed: Dec. 19, 2024

(51) Int. Cl. H01L 23/538; H01L 21/56; H01L 21/768; H01L 23/00; H01L 23/498; H01L 23/60; H01L 25/16; H05K 1/18

(52) U.S. Cl. CPC H10W 70/65; H05K 1/181; H10W 20/023; H10W 70/611; H10W 74/016; H10W 42/60; H10W 74/10; H10W 90/00; H10W 90/724

(57) ABSTRACT

Double-sided integrated circuit (IC) packages with bottom IC(s) having backside metallization, and related fabrication methods. The back side of a bottom IC(s) coupled to the bottom side of a routing substrate also includes a backside metallization. The backside metallization can be provided as a backside metallization layer formed on or adjacent to the back side of the bottom IC(s) to provide radio-frequency (RF) shielding; as a backside metallization layer/metal pads formed on or adjacent to the back side of the bottom IC(s) and thermally coupled to the bottom IC(s) to provide a heat dissipation device to facilitate enhanced dissipation of heat generated by the bottom IC(s); and as backside metallization pads formed on or adjacent to the back side of the bottom IC(s) and electrically connected to metal pads exposed from the IC to provide direct electrical backside connections to the bottom IC(s).

### TECHNICAL FIELD

The field of the disclosure relates to integrated circuit (IC) packages, and more particularly to double-sided IC packages that have electrical components mounted to both sides of a routing substrate to support more complex IC packages.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a substrate as a routing substrate (e.g., a package substrate) to provide physical support and an electrical interface to the die(s). The die(s) is electrically interfaced to metal interconnects (e.g., metal traces) exposed in an upper layer of the substrate as part of signal routing paths. The substrate also includes one or more metallization layers that include metal interconnects (e.g., metal traces, metal lines) with vertical interconnect accesses (vias) coupling the metal interconnects together between adjacent metallization layers to provide electrical interfaces between the dies. If the substrate is a package substrate, the substrate also includes a lower, outer metallization layer that includes metal interconnects coupled to external metal interconnects (e.g., ball grid array (BGA) interconnects) to provide an external interface between the dies in the IC package. The external metal interconnects can also be coupled (e.g., soldered) to traces in a printed circuit board (PCB) to attach the package to the PCB and interface its die(s) with the circuitry of the PCB.

IC packages can be provided as double-sided IC packages. In double-sided IC packages, electrical components (e.g., dies, filter ICs, passive electrical devices) are mounted on both the bottom and top sides of a substrate. A double-sided IC package facilitates supporting inclusion of a greater number of electrical components in a given footprint size by being able to be mount electrical components on both the top and bottom sides of the substrate. Signals are routed to the electrical components through the substrate as a routing substrate. The electrical components are encapsulated in a molding compound wherein top and bottom mold layers are formed on each side of the substrate. External interconnects are formed in the bottom mold layer to facilitate the double-sided IC being electrically connected to an external circuit board. The external interconnects extend to and are electrically coupled to metal interconnects in the bottom metallization layer of the package substate. The external interconnects are also exposed from the bottom surface of the bottom mold layer to be able to be connected to a circuit board. In this manner, the external interconnects provide signal routing paths from outside the double-sided IC package, through the bottom mold layer, and to the substrate and the electrical components electrically coupled to the substrate.

The external interconnects may be solder balls that are formed in openings formed in the bottom mold layer. The external interconnects may also be metal (e.g., copper) pillars that are formed in the bottom mold layer. Metal pillars allow the external interconnects to be provided at a smaller pitch and with less tolerance to be connected to metal interconnects in the bottom metallization layer of the substrate. However, if metal pillars are employed, a pre-solder cap or other metal layer is typically formed on the bottom surface of the metal pillar to enhance electrical conductivity, improve solderability, and/or to provide corrosion resistance.

### SUMMARY OF THE DISCLOSURE

Aspects disclosed herein include double-sided integrated circuit (IC) packages with a bottom IC(s) having a backside metallization. Related fabrication methods are also disclosed. The double-sided IC package includes a substrate with electrical components (e.g., dies, filter ICs, passive electrical devices) mounted on both the bottom and top sides of a substrate to facilitate providing a larger number of electrical components in the IC package for a given footprint size. The substrate includes metallization layers that include metal interconnects (e.g., metal lines, metal traces) to provide signal paths to the electrical components coupled to the substrate. The electrical components in respective top and bottom layers (e.g., top and bottom mold layers) are formed on the respective top and bottom sides of the substrate. External interconnects (e.g., solder balls, metal pillars) are formed in the bottom layer and extend to and are electrically coupled to a bottom metallization layer in the substrate to provide external signal routing paths through the substrate to the electrical components. In exemplary aspects, the backside of a bottom IC(s) coupled to the bottom side of the substrate also includes a backside metallization. The backside metallization can be provided as a backside metallization layer formed on the backside of the bottom IC(s) to provide a radio-frequency (RF) shield to the bottom IC(s). The backside metallization can also be provided as a backside metallization layer(s) formed on the backside of the bottom IC(s) and thermally coupled to the bottom IC(s) to provide a heat dissipation device to facilitates enhanced dissipation of heat generated by the bottom IC(s).

In another example, the backside metallization can also be provided as backside metal interconnects (e.g., metal pads) formed on to the back side of the bottom IC(s) and electrically connected to metal pads exposed from the IC to provide direct electrical backside connections to the bottom IC(s). A non-limiting advantage of providing the backside metal interconnects to provide direct electrical backside connections to the bottom IC(s) is that this may avoid the need or desire to provide an additional redistribution layer (RDL) on the bottom layer to facilitate external interconnections to the IC package. The backside metal interconnects providing direct electrical backside connections to the bottom IC(s) may relax routing congestion enough to allow the metal pillars and backside metal pads to be in alignment with metal pads of the intended connected circuit board without the need for redistributing these metal interconnections through a separate RDL. Providing direct connections to the bottom IC(s) can also increase the stability of the IC package and the bottom IC(s) within the IC package.

The backside metallization is formed from a metal material that can be chosen to enhance electrical conductivity, improve solderability, and/or to provide corrosion resistance. For example, the backside metallization can be formed as a metal layer of a metal material, such as Nickel, Aluminum, Titanium, steel, or a compound thereof. As another example, if the backside metallization is provided as backside metal interconnects electrically connected to the bottom IC to provide signal routing paths directly to the IC, the backside metal interconnects can be formed as solder balls in contact with exposed metal pads in a metallization layer in the bottom IC.

Another advantage of providing the backside metallization on the bottom IC in the IC package is that the same process that is used to form metal plating on metal pillars extending through the bottom layer to provide external interconnects can also be used to form the backside metallization. For example, in a fabrication process of the IC package, the bottom layer can be grinded down to the back side of the bottom IC(s) thereby exposing both the back side of the bottom IC(s) and bottom surfaces of the metal pillars. Thereafter, a bottom metal layer can be formed on the processed bottom side of the bottom layer in contact with both the back side of the bottom IC(s) and the bottom side of the metal pillars in the same processing step. The metal layer can then be processed (e.g., using lithography) to form openings therein leaving separate metal layers on the bottom sides of the metal pillars and as a backside metallization on the bottom IC(s). If the backside metallization is to provide direct connections to the bottom IC(s), the bottom metal layer will have also been processed to form individual backside metallization pads coupled to the bottom IC(s).

In this regard, in one exemplary aspect, an IC package is provided. The IC package comprises a substrate comprising a top side and a bottom side opposite the top side. The IC package also comprises a top layer adjacent to the top side of the substrate, the top layer comprising: an electrical component electrically coupled to the top side of the substrate. The IC package also comprises a bottom layer adjacent to the bottom side of the substrate, the bottom layer comprising: a bottom IC, comprising: a front side adjacent to the substrate and electrically coupled to the substrate; and a back side opposite the front side of the bottom IC, the back side exposed from the bottom layer. The IC package also comprises a backside metallization on the back side of the bottom IC.

In another exemplary aspect, a method of fabricating an IC package is provided. The method comprises providing a substrate comprising a top side and a bottom side opposite the top side. The method also comprises electrically coupling an electrical component to the top side of the substrate. The method also comprises forming a top layer adjacent to the top side of the substrate, the top layer comprising the electrical component. The method also comprises electrically coupling a front side of a bottom IC to the substrate. The method also comprises forming a bottom layer adjacent to the bottom side of the substrate, the bottom layer comprising the bottom IC with a back side of the bottom IC exposed from the bottom layer. The method also comprises forming a backside metallization on the back side of the bottom IC.

In another exemplary aspect, an electronic assembly is provided. The electronic assembly comprises a circuit board comprising a metallization layer comprising a plurality of metal interconnects. The electronic assembly also comprises an IC package comprising a substrate comprising a top side and a bottom side opposite the top side; a top layer adjacent to the top side of the substrate, the top layer comprising an electrical component electrically coupled to the top side of the substrate; a bottom layer adjacent to the bottom side of the substrate, the bottom layer comprising a bottom IC, comprising a front side adjacent to the substrate and electrically coupled to the substrate; a back side opposite the front side of the bottom IC, the back side exposed from the bottom layer; and a plurality of metal pads exposed from the back side of the bottom IC. The IC package also comprises a plurality of backside metal interconnects each coupled to a metal pad of the plurality of metal pads of the bottom IC and each coupled to a metal interconnect of the plurality of metal interconnects of the circuit board.

### BRIEF DESCRIPTION OF THE FIGURES

FIGS. 1A and 1B are side views of an exemplary electronic assembly that includes an exemplary integrated circuit (IC) package in the form of a double-sided IC package that includes a substrate with top and bottom layers encapsulating respective top and bottom electrical components coupled to respective top and back sides of the substrate, and wherein the IC package includes a backside metallization for a bottom IC, and wherein the backside metallization is provided as backside metal interconnects to provide direct external connections to the bottom IC;

FIG. 2 is a side view of another exemplary double-sided IC package that does not include a backside metallization for a bottom IC;

FIG. 3 is a side view of another exemplary double-sided IC package that includes a backside metallization in the form of backside metal interconnects formed from metal layers and directly coupled to a bottom IC(s) to provide direct external connections to the bottom IC, and wherein solder balls are coupled to the backside metal interconnects to extend the interconnections of the backside metal interconnects to a circuit board;

FIG. 4 is a side view of another exemplary double-sided IC package similar to the double-sided IC package in FIG. 3, but wherein the backside metallization for one of the bottom ICs is provided in the form of solder balls;

FIG. 5 is a flowchart illustrating an exemplary fabrication process of fabricating a double-sided IC package that includes a backside metallization for a bottom IC, including, but not limited to, the IC packages in FIGS. 1A-1B, 3, and 4;

FIGS. 6A-6D is a flowchart illustrating another exemplary process of fabricating a double-sided IC package that includes a backside metallization for a bottom IC in the form of backside metal interconnects to provide direct external connections to the bottom IC, including, but not limited to, the IC packages in FIGS. 1A-1B, 3, and 4;

FIG. 7A-7G are exemplary fabrication stages during fabrication of the double-sided IC package according to the exemplary fabrication process in FIGS. 6A-6D;

FIG. 8 is a side view of another exemplary double-sided IC package that includes a substrate with top and bottom layers encapsulating respective top and bottom electrical components coupled to respective top and bottom sides of the substrate, and wherein the IC package includes a backside metallization in the form of a backside metallization layer for a bottom IC that can provide a radio-frequency (RF) shield and/or a heat dissipation device for the bottom IC;

FIGS. 9A-9C illustrate exemplary bottom views of the bottom IC in the IC package in FIG. 8 with alternative backside metallization layers;

FIGS. 10A-10D is a flowchart illustrating another exemplary process of fabricating a double-sided IC package that includes a backside metallization for a bottom IC in the form of a backside metallization layer, including, but not limited to, the double-sided IC packages in FIGS. 8-9C;

FIG. 11A-11G are exemplary fabrication stages during fabrication of the double-sided IC package according to the exemplary fabrication process in FIGS. 10A-10D;

FIG. 12 is a block diagram of an exemplary electronic device in the form of a processor-based system that includes one or more IC packages that include a substrate with top and bottom layers encapsulating respective top and bottom electrical components coupled to respective top and bottom sides of the substrate, and wherein the IC package includes a backside metallization for a bottom IC, including, but not limited to, the IC packages in FIGS. 1A-1B, 3, 4, 7G, 8-9C, and 11G, and that can be fabricated according to a fabrication process, including, but not limited to, the exemplary fabrication processes in FIGS. 5, 6A-6D, and 10A-10D; and

FIG. 13 is a block diagram of an exemplary wireless communications device that includes one or more IC packages that include a substrate with top and bottom layers encapsulating respective top and bottom electrical components coupled to respective top and bottom sides of the substrate, and wherein the IC package includes a backside metallization for a bottom IC, including, but not limited to, the IC packages in FIGS. 1A-1B, 3, 4, 7G, 8-9C, and 11G, and that can be fabricated according to a fabrication process, including, but not limited to, the exemplary fabrication processes in FIGS. 5, 6A-6D, and 10A-10D.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include double-sided integrated circuit (IC) packages with a bottom IC(s) having a backside metallization. Related fabrication methods are also disclosed. The double-sided IC package includes a substrate with electrical components (e.g., dies, filter ICs, passive electrical devices) mounted on both the bottom and top sides of a substrate to facilitate providing a larger number of electrical components in the IC package for a given footprint size. The substrate includes metallization layers that include metal interconnects (e.g., metal lines, metal traces) to provide signal paths to the electrical components coupled to the substrate. The electrical components in respective top and bottom layers (e.g., top and bottom mold layers) are formed on the respective top and bottom sides of the substrate. External interconnects (e.g., solder balls, metal pillars) are formed in the bottom layer and extend to and are electrically coupled to a bottom metallization layer in the substrate to provide external signal routing paths through the substrate to the electrical components. In exemplary aspects, the backside of a bottom IC(s) coupled to the bottom side of the substrate also includes a backside metallization. The backside metallization can be provided as a backside metallization layer formed on the backside of the bottom IC(s) to provide a radio-frequency (RF) shield to the bottom IC(s). The backside metallization can also be provided as a backside metallization layer(s) formed on the backside of the bottom IC(s) and thermally coupled to the bottom IC(s) to provide a heat dissipation device to facilitates enhanced dissipation of heat generated by the bottom IC(s).

In another example, the backside metallization can also be provided as backside metal interconnects (e.g., metal pads) formed on to the backside of the bottom IC(s) and electrically connected to metal pads exposed from the IC to provide direct electrical backside connections to the bottom IC(s). A non-limiting advantage of providing the backside metal interconnects to provide direct electrical backside connections to bottom IC(s) is that this may avoid the need or desire to provide an additional redistribution layer (RDL) on the bottom layer to facilitate external interconnections to the IC package. The backside metal interconnects providing direct electrical backside connections to the bottom IC(s) may relax routing congestion enough to allow the metal pillars and backside metal pads to be formed in alignment with metal pads of the intended connected circuit board without the need for redistributing these metal interconnections through a separate RDL. Providing direct connections to the bottom IC(s) can also increase the stability of the IC package and the bottom IC(s) within the IC package.

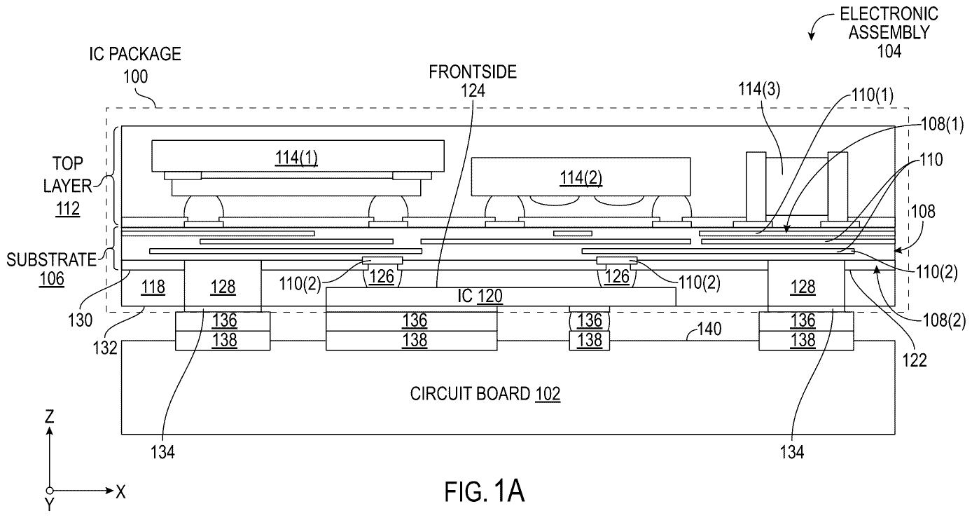

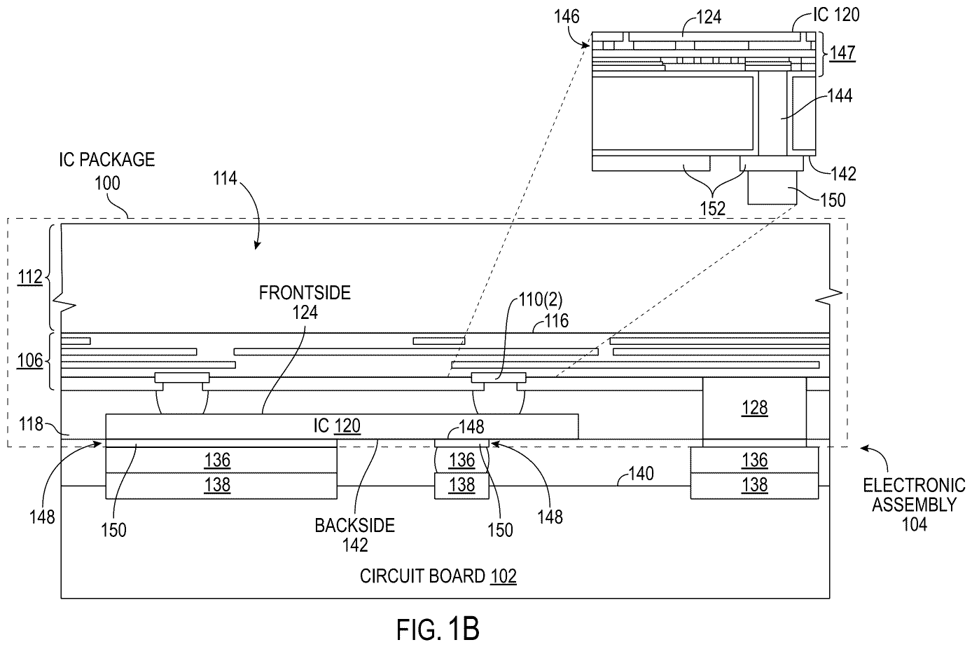

In this regard, FIGS. 1A and 1B are side views of an exemplary IC package 100 in the form of a double-sided IC package that is coupled to a circuit board 102 to form an electronic assembly 104. The double-sided IC package 100 includes a substrate 106 that is a routing substrate (and can also be referred to as a “package substrate”) that includes a plurality of metallization layers 108 that each include a plurality of metal interconnects 110 (e.g., metal lines, metal traces) configured to carry electrical signals. The substrate 106 may for example, be a laminate substrate comprised of a plurality of the metallization layers 108 laminated to each other. Alternatively or in addition, the substrate 106 can include one or more embedded trace substrate (ETS) layers as part of the metallization layers 108, wherein the ETS layers are fabricated on each other and the metal interconnects 110 formed embedded in a dielectric layer of a metallization layer 108.

In this example, as shown in FIG. 1A, with the IC package 100 being a double-sided IC package, the IC package 100 includes a top layer 112 that includes one or more electrical components 114(1)-114(3) (e.g., ICs, passive electrical components, filters) adjacent to a top side 116 of the substrate 106. The top layer 112 is a mold layer in this example that is formed from a molding compound that is disposed on the electrical components 114(1)-114(3) and the exposed top side 116 of the substrate 106 to encapsulate and insulates the electrical components 114(1)-114(3) from each other. In this regard, the top layer 112 as shown includes the electrical components 114(1)-114(3). The electrical components 114(1)-114(3) are electrically coupled to upper metal interconnects 110(1) in an upper metallization layer 108(1) of the substrate 106 on or adjacent to the top side 116. In this manner, electrical signals can be routed to the electrical components 114(1)-114(3) through the substrate 106. The IC package 100 also includes a bottom layer 118 that includes a bottom IC 120 adjacent to a bottom side 122 of the substrate 106 opposite the top side 116 in the vertical direction (Z-axis direction). By “bottom” IC 120, this is simply convenient nomenclature used to indicate that the IC is below the substrate 106 in FIG. 1A in the vertical direction (Z-axis direction), but if the substrate 106 were flipped upside down, the bottom IC 120 would be above the substrate 106. The bottom layer 118 is a bottom mold layer that is also formed from a molding compound that is disposed on the bottom IC 120 and the exposed bottom side 122 of the substrate 106 to encapsulate and insulate the bottom IC 120. In this regard, the bottom layer 118 as shown includes the bottom IC 120. The bottom IC 120 is electrically coupled to bottom metal interconnects 110(2) in a bottom metallization layer 108(2) of the substrate 106 on or adjacent to the bottom side 122 of the substrate 106. In this manner, electrical signals can be routed to the bottom IC 120 through the substrate 106.

With continuing reference to FIG. 1A, the bottom IC 120 is electrically coupled to the substrate 106 (and metal interconnects 110 therein), wherein electrical signals can be routed to the bottom IC 120 through the substrate 106. In this example, the bottom IC 120 is electrically coupled to the substrate 106 through a front side 124 of the bottom IC 120. The front side 124 of the bottom IC 120 refers to a top surface of the bottom IC 120 where actual electronic components like transistors and wiring are visible, typically including the identifying markings and pin connections, which are the metal pads that connect to the external pins. The bottom IC 120 is oriented in the bottom layer 118 such that the front side 124 of the bottom IC 120 is adjacent to the bottom side 122 of the substrate 106. In this example, metal interconnects 126 (e.g., in a ball grid array (BGA)) of the bottom IC 120 are coupled to bottom metal interconnects 110(2) in the bottom metallization layer 108(2) of the substrate 106. For example, the metal interconnects 126 of the bottom IC 120 may be soldered to bottom metal interconnects 110(2) in the bottom metallization layer 108(2) of the substrate 106 through a soldering or solder reflow process.

Also, as shown in FIG. 1A, to provide external connections between the IC package 100 and its electrical components 114(1)-114(3) in the top layer 112 and the bottom IC 120 in the bottom layer 118, vertical interconnects 128 are provided that extend through the bottom layer 118 and are electrically coupled to metal interconnects 110 in the substrate 106. In this example, the vertical interconnects 128 are metal pillars (e.g., copper pillars) that are formed in the bottom layer 118 extending through both a top side 130 and bottom side 132 of the bottom layer 118. Metal pillars have an advantage of allowing for the vertical interconnects 128 to be provided at a smaller pitch size to increase routing density in the IC package 100. However, the vertical interconnects 128 could be provided as solder balls or bumps or any other type of metal interconnect. Bottom surfaces 134 of the vertical interconnects 128 are exposed from the bottom side 132 of the bottom layer 118. In this manner, when coupling the IC package 100 to the circuit board 102, additional metal interconnects 136 (e.g. metal layers, metal pads, metal balls, solder balls) can be formed on the bottom surfaces 134 of the vertical interconnects 128 to couple the vertical interconnects 128 to metal pads 138 exposed from a top surface 140 of the circuit board 102.

FIG. 1B is a close-up partial side view of the IC package 100 in FIG. 1A. In this example, it is desired to also be able to provide electrical connectivity to the bottom IC 120 through a back side 142 of the bottom IC 120. The back side 142 of the bottom IC 120 is opposite the front side 124 of the bottom IC 120 in the vertical direction (Z-axis direction) in this example. The back side 142 may be a silicon surface for example. The back side 142 of the bottom IC 120 in this example includes the underside of the semiconductor wafer that makes up the core of the bottom IC 120, essentially the opposite side from where the visible pins and connections are located on the front side 124 of the bottom IC 120. The back side 142 of the bottom IC 120 consists of a smooth, polished silicon surface with potential for additional processing depending on the specific IC design and manufacturing techniques. As shown in FIG. 1B, the bottom IC 120 can include through-silica vias (TSVs) 144 that extend through the silicon substrate of the bottom IC 120 and its die therein and extend to the metallization layers 146 formed as part of a back-end-of-line (BEOL) interconnect structure 147 of the bottom IC 120. Providing electrical connectivity to the bottom IC 120 through the back side 142 of the bottom IC 120 can increase routing density in the IC package 100, because this allows electrical signals to be routed from the circuit board 102 directly to the bottom IC 120, as opposed to having to be solely routed through the vertical interconnects 128 and the substrate 106 to the front side 124 of the bottom IC 120, as shown FIG. 1A. Providing electrical connectivity to the bottom IC 120 through the back side 142 of the bottom IC 120 can also increase the stability of the connectivity between the IC package 100 and the circuit board 102.

In this regard, as shown in FIG. 1B, a backside metallization 148 in the form of backside metal interconnects 150 is formed in contact with the back side 142 of the bottom IC 120. In this example, the backside metal interconnects 150 are formed from a metal layer that is disposed on the back side 142 of the bottom IC 120. In this example, as shown in FIG. 1B, the backside metal interconnects 150 are formed in contact with metal pads 152 exposed from the back side 142 of the bottom IC 120. In this manner, the backside metal interconnects 150 provide additional electrical signal paths to the bottom IC 120 to allow for direct connection signal paths between the bottom IC 120 and the circuit board 102, as shown FIG. 1A. A non-limiting advantage of providing the backside metal interconnects 150 to provide direct electrical backside connections to the bottom IC 120 is that this may avoid the need or desire to provide an additional redistribution layer (RDL) on the bottom layer 118 to facilitate external interconnections to the IC package 100. The backside metal interconnects 150 providing direct electrical backside connections to the bottom IC 120 may relax routing congestion in the IC package 100 enough to allow the vertical interconnects 128 and backside metal interconnects 150 of the bottom IC 120 to be in alignment with the metal pads 138 of the circuit board 102 (FIG. 1A) without the need for redistributing these metal interconnections through a separate RDL. Providing direct connections to the bottom IC 120 can also increase the stability of the IC package 100 connection to the circuit board 102 and the bottom IC 120 within the IC package 100.

The backside metallization 148 in the form of the backside metal interconnects 150 can be formed from a metal material that can be chosen to enhance electrical conductivity, improve solderability, and/or to provide corrosion resistance. For example, the backside metal interconnects 150 can be formed as a metal layer of metal material, such as Nickel, Aluminum, Titanium, steel or a compound thereof. As another example, as discussed in more detail below, the backside metal interconnects 150 can be formed as solder balls in contact with exposed metal pads in a metallization layer in the bottom IC 120.

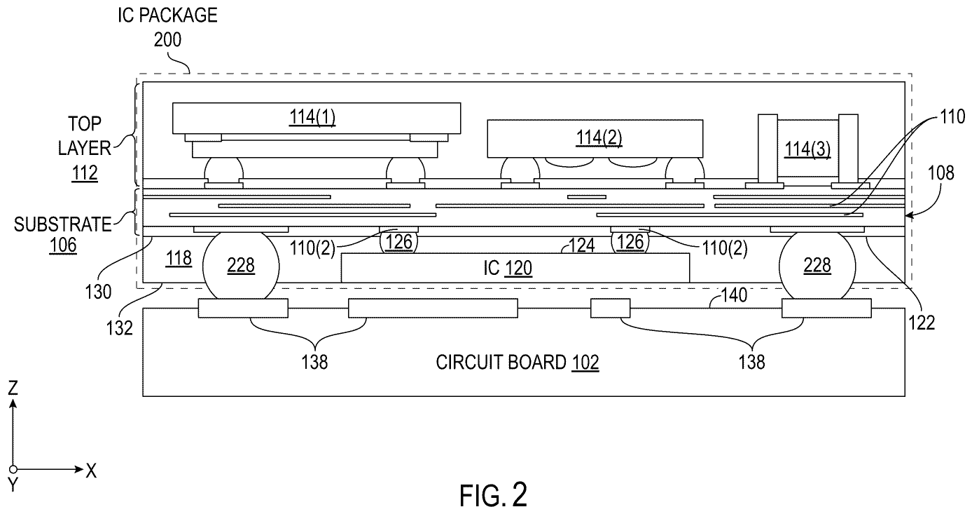

For comparison purposes, FIG. 2 is a side view of another exemplary double-sided IC package 200 similar to the IC package 100 in FIGS. 1A and 1B; however, the IC package 200 in FIG. 2 does not include a backside metallization for connectivity to the back side 142 of the bottom IC 120. Thus, in the IC package 200 in FIG. 2, all signal routing between the circuit board 102 and the bottom IC 120 must be routed through vertical interconnects 228 (solder balls in this example), to the substrate 106, and then to the front side 124 of the bottom IC 120.

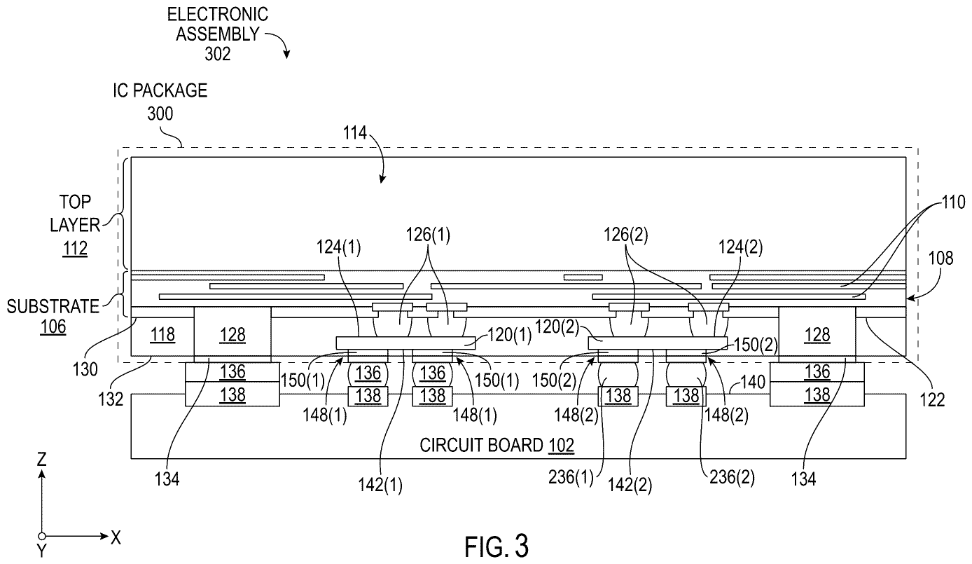

FIG. 3 is a side view of another exemplary double-sided IC package 300 that is similar to the IC package 100 in FIGS. 1A and 1B. Common elements between the IC package 100 in FIGS. 1A and 1B and the IC package 300 in FIG. 3 are shown with common element numbers. However, in this example IC package 300 in FIG. 3, the bottom layer 118 includes two bottom ICs 120(1), 120(2). The front sides 124(1), 124(2) of the respective bottom ICs 120(1), 120(2) are electrically connected to the bottom side 122 of the substrate 106 through metal interconnects 126(1), 126(2), like the bottom IC 120 is coupled to the bottom side 122 of the substrate 106 in the IC package 100 in FIGS. 1A and 1B. Backside metallizations 148(1), 148(2) in the form of respective backside metal interconnects 150(1), 150(2) are formed on the back sides 142(1), 142(2) of the respective bottom ICs 120(1), 120(1) similar to the backside metal interconnects 150 provided in the IC package 100 in FIGS. 1A and 1B. However, in the IC package 300 in FIG. 3, instead of additional metal interconnects 136 being formed on the backside metal interconnects 150(1), 150(2), solder bumps or balls 236(1), 236(2) are used to couple the backside metal interconnects 150(1), 150(2) to the metal pads 138 exposed from the top surface 140 of the circuit board 102.

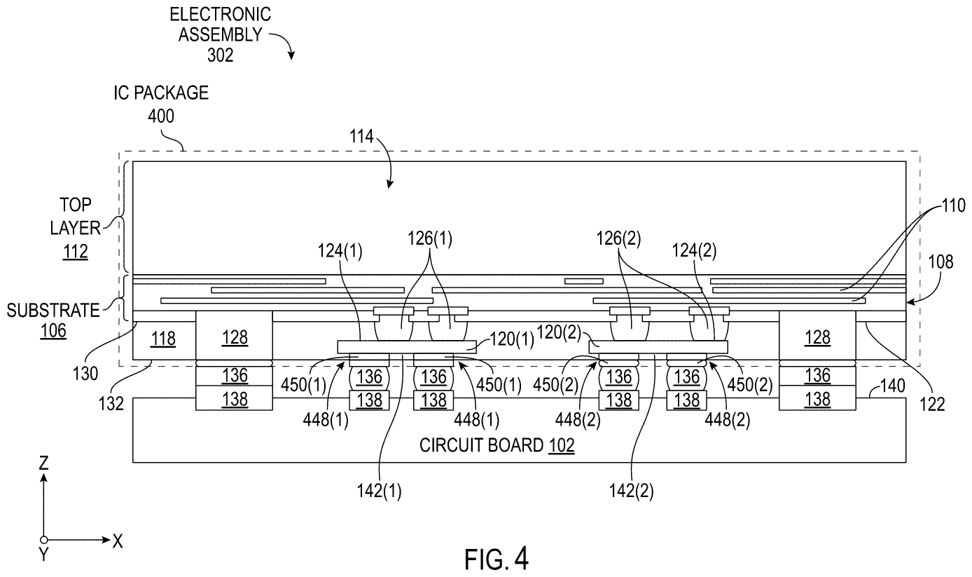

FIG. 4 is a side view of another exemplary double-sided IC package 400 that is similar to the IC package 300 in FIG. 3. Common elements between the IC package 300 in FIG. 3 and the IC package 400 in FIG. 4 are shown with common element numbers. However, in this example IC package 400 in FIG. 4, backside metallizations 448(1), 448(2) for the bottom ICs 120(1), 120(2) are provided in the form of solder bumps or balls as the backside metal interconnects 450(1), 450(2), instead of metal layers like the backside metal interconnects 150(1), 150(2) in the IC package 300 in FIG. 3.

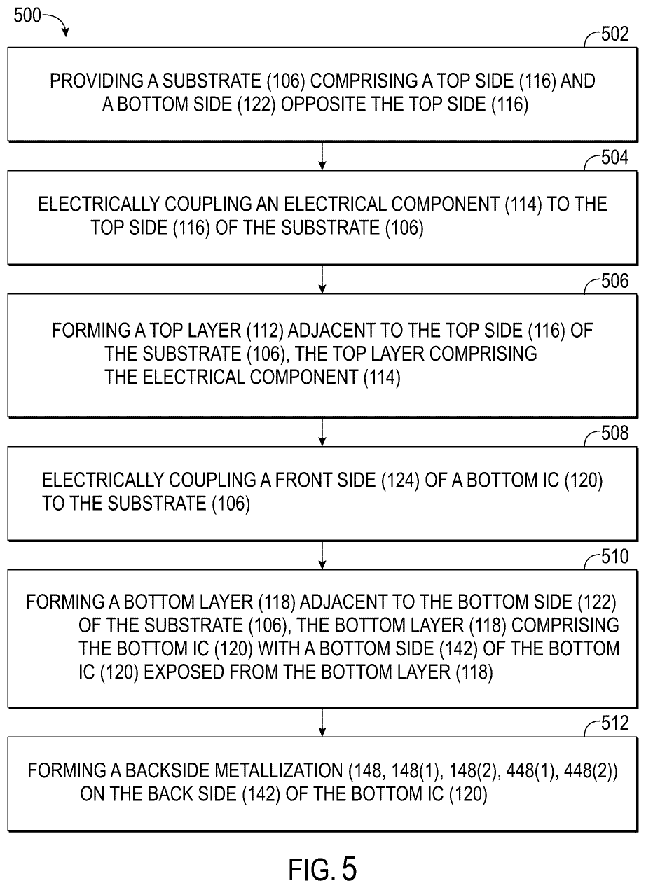

IC packages that includes a substrate with top and bottom layers encapsulating respective top and bottom electrical components coupled to respective top and bottom sides of the substrate, and wherein the IC package includes a backside metallization for a bottom IC, including, but not limited to, the IC packages 100, 300, 400 in FIGS. 1A-1B, 3, and 4, can be fabricated according to a fabrication process. In this regard, FIG. 5 is a flowchart illustrating an exemplary fabrication process 500 of fabricating IC packages that include a substrate with top and bottom layers encapsulating respective top and bottom electrical components coupled to respective top and bottom sides of the substrate, and wherein the IC package includes a backside metallization for a bottom IC, including, but not limited to, the IC packages 100, 300, 400 in FIGS. 1A-1B, 3, and 4. The fabrication process 500 in FIG. 5 is described with regard to the exemplary IC packages 100, 300, 400 in FIGS. 1A-1B, 3, and 4, but such is not limiting.

In this regard, as shown in FIG. 5, a first step of the fabrication process 500 can be providing a substrate 106 comprising a top side 116 and a bottom side 122 opposite the top side 116 (block 502 in FIG. 5). A next step in the fabrication process 500 can be electrically coupling an electrical component 114 to the top side 116 of the substrate 106 (block 504 in FIG. 5). A next step in the fabrication process 500 can be forming a top layer 112 adjacent to the top side 116 of the substrate 106, the top layer 112 comprising the electrical component 114 (block 506 in FIG. 5). A next step in the fabrication process 500 can be electrically coupling a front side 124 of a bottom IC 120 to the substrate 106 (block 508 in FIG. 5). A next step in the fabrication process 500 can be forming a bottom layer 118 adjacent to the bottom side 122 of the substrate 106, the bottom layer 118 comprising the bottom IC 120 with a back side 142 of the bottom IC 120 exposed from the bottom layer 118 (block 510 in FIG. 5). A next step in the fabrication process 500 can be forming a backside metallization 148, 148(1), 148(2), 448(1), 448(2) on the back side 142 of the bottom IC 120 (block 512 in FIG. 5).

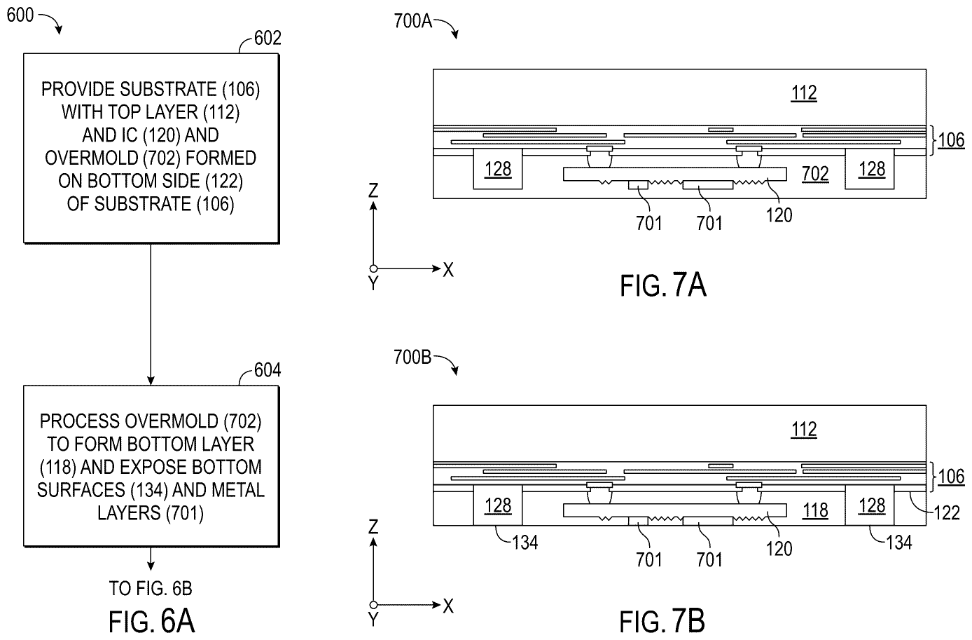

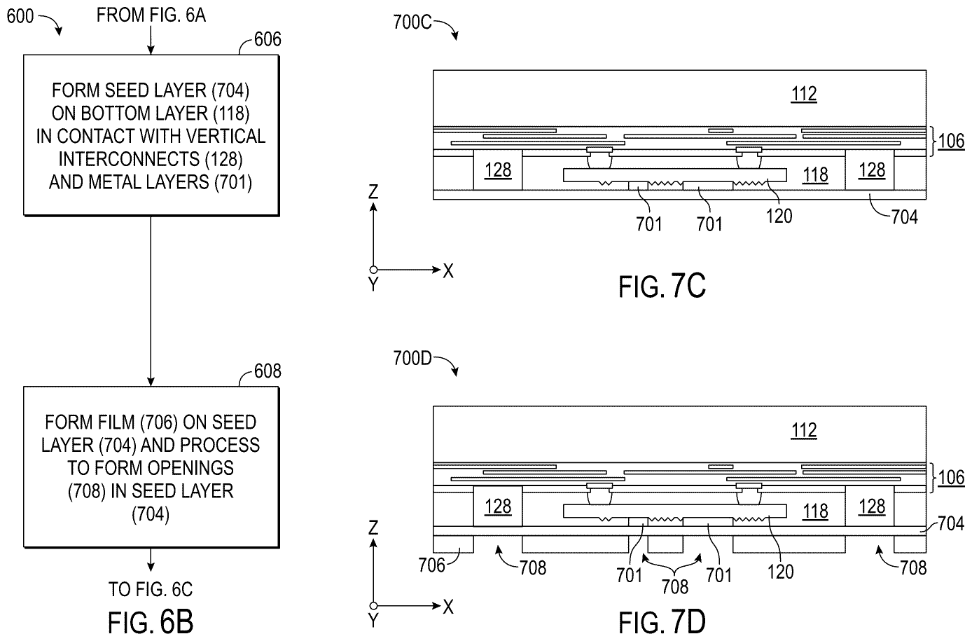

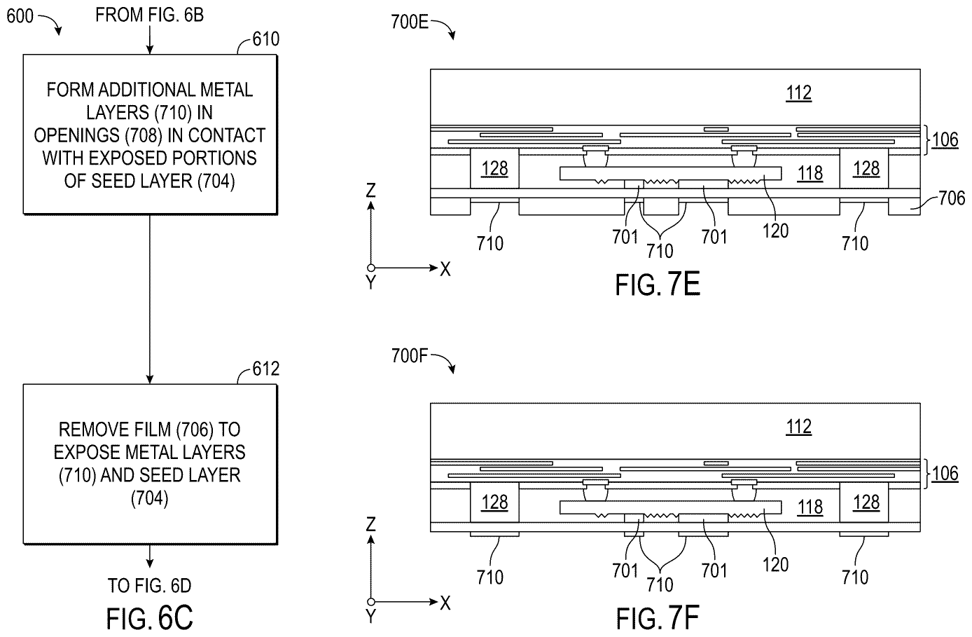

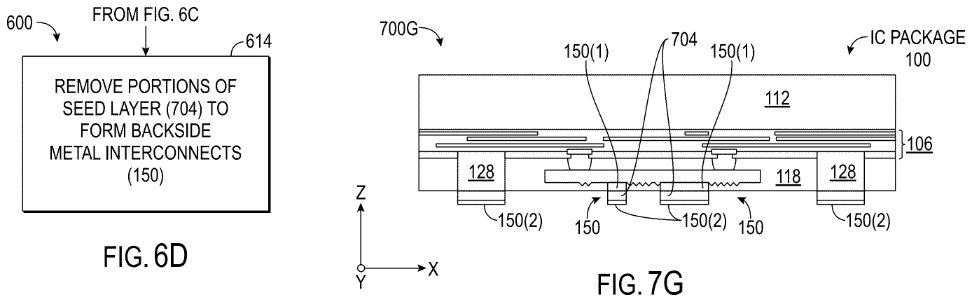

FIGS. 6A-6D is a flowchart illustrating another exemplary process 600 of fabricating a double-sided IC package that includes a backside metallization for a bottom IC in the form of backside metal interconnects to provide direct external connections to the bottom IC, including, but not limited to, the IC packages 100, 300, 400 in FIGS. 1A-1B, 3, and 4. FIG. 7A-7G are exemplary fabrication stages 700A-700G during fabrication of the double-sided IC package according to the exemplary fabrication process 600 in FIGS. 6A-6D. The exemplary process 600 in FIGS. 6A-6D will be discussed in reference to the IC package 100 in FIGS. 1A and 1B, but such is not limiting.

In this regard, as shown in the exemplary fabrication stage 700A in FIG. 7A, a first fabrication step can be to provide the substrate 106 with the top layer 112 disposed thereon (block 602 in FIG. 6A). The vertical interconnects 128 and metal layers 701 that will form a portion of the backside metal interconnects 150 have been formed in the bottom layer 118 and on the back side 142 of the bottom IC 120. An overmold 702 of a molding compound is disposed on the bottom side 122 of the substrate 106 and encapsulates the vertical interconnects 128 and the metal layers 701. This is to prepare the bottom layer 118 to be formed on the bottom side 122 of the substrate 106. Then, as shown in the exemplary fabrication stage 700B in FIG. 7B, the overmold 702 is processed, by removing or grinding down the overmold 702 to the metal layers 701 to form the final bottom layer 118 for the IC package 100 (block 604 in FIG. 6A). This process may also involve grinding down of the vertical interconnects 128 to form the bottom surfaces 134 of the vertical interconnects 128 to be planar or substantially planar with the metal layers 701 so that both the metal layers 701 and the bottom surfaces 134 of the vertical interconnects 128 are exposed from the bottom layer 118.

Then, as shown in the exemplary fabrication stage 700C in FIG. 7C, a next step in the fabrication process 600 can be to form a seed layer 704 on the bottom layer 118 and in contact with the bottom surfaces 134 of the vertical interconnects 128 and the metal layers 701 (block 606 in FIG. 6B). For example, this process step can be performed if an electroplating process is to be used to form additional metal layers on the metal layers 701 that will form the backside metal interconnects 150. The seed layer 704 may be formed on the bottom layer 118 by a sputtering process. The seed layer 704 is a conductive material that is intended to provide a good material bond to the bottom surfaces 134 of the vertical interconnects 128 and the metal layers 701 to improve conductivity for later formation of additional metal interconnects as part of the metal layers 701 to provide direct connections to a circuit board. Then, as shown in the exemplary fabrication stage 700D in FIG. 7D, a next step in the fabrication process 600 can be to deposit a film 706 on the seed layer 704 and to process the film 706 to pattern the film 706 as a patterning layer (e.g., by an exposure and etch process), to create openings 708 that extend to the seed layer 704 adjacent to the bottom surfaces 134 of the vertical interconnects 128 and the metal layers 701 (block 608 in FIG. 6B). Then, as shown in exemplary fabrication stage 700E in FIG. 7E, a next step in the fabrication process 600 can be to form additional metal layers 710 in the openings 708 and in contact with the exposed portions of the seed layer 704 (block 610 in FIG. 6C). This step can be performed for example by an electroless plating process as an example. In this manner, the additional metal layers 710 that are added to the vertical interconnects 128 and metal layers 701 for the backside metal interconnects 150 can be formed in the same process step.

Then, as shown in the exemplary fabrication stage 700F in FIG. 7F, a next step in the fabrication process 600 can be to remove the film 706 to expose just the additional metal layers 710 (block 612 in FIG. 6C). Then, aa shown in the exemplary fabrication stage 700G in FIG. 7G, a next step in the fabrication process 600 can be to remove the portions of the seed layer 704 that are outside of the additional metal layers 710 (block 614 in FIG. 6D). After this step, the combination of the metal layers 701, remnant seed layer 704 coupled to the metal layers 701, and the additional metal layers 710 formed on the seed layer 704 form the backside metal interconnects 150. This creates the IC package 100 that is ready to be coupled to a circuit board with the backside metal interconnects 150 providing an ability to provide direct electrical connections between the bottom IC 120 and the circuit board for signal routing.

Alternatively, an electroless plating process could be employed to form the additional metal layers on the metal layers 701 to form the backside metal interconnects 150 in the IC package 100 in FIG. 7G. In this regard, the seed layer 704 would not be disposed on the bottom layer 118 and in contact with the exposed bottom surfaces 134 of the vertical interconnects 128 and metal layers 701, as shown in FIG. 7B. Alternatively, an electroless plating could be performed on the exposed bottom surfaces 134 of the vertical interconnects 128 and metal layers 701 to build up metal layers thereon. Electroless plating, also known as electroless deposition, is a chemical process that deposits a layer of metal onto a surface without using an external electrical currently. In this regard, what constitutes the additional metal layers from the seed layer 704 and additional metal layers 150(2) in the IC package 100 in FIG. 7G could be formed by depositing metal material on the exposed bottom surfaces 134 of the vertical interconnects 128 and metal layers 701. For example, the process can include pretreatment of the exposed bottom surfaces 134 of the vertical interconnects 128 and metal layers 701 to clean their surfaces to remove contaminants, sensitization of the exposed bottom surfaces 134 of the vertical interconnects 128 and metal layers 701 to reduce the active metal to serve as a catalytic site for the templation of the active metal, activation of the sensitized exposed bottom surfaces 134 of the vertical interconnects 128 and metal layers 701 with metal nanoparticles (e.g., silver, gold, palladium) to accelerate deposition of additional metal material by acting as a catalytic seed, and then an electroless deposition of metal material thereon.

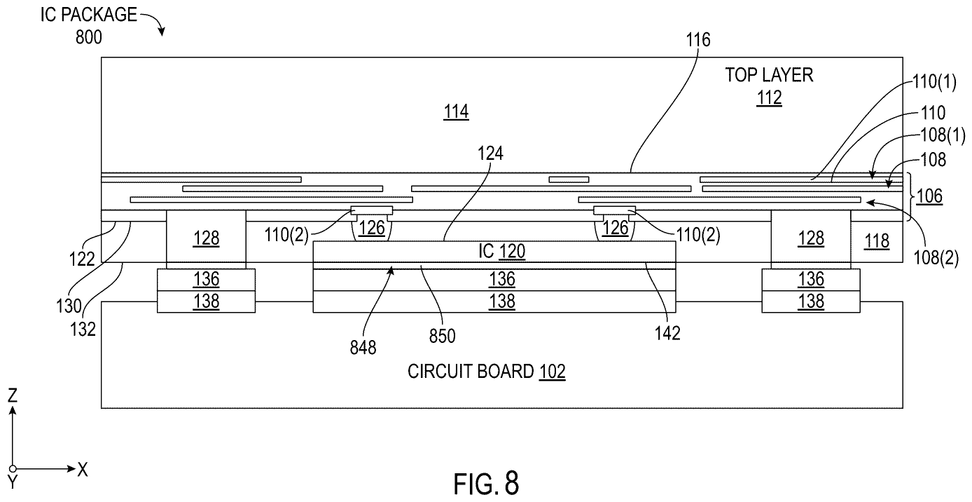

FIG. 8 is a side view of another exemplary double-sided IC package 800 that includes a backside metallization in the form of a backside metallization layer for a bottom IC. The IC package 800 in FIG. 8 is similar to the IC package 100 in FIGS. 1A and 1B. However, in this example, as discussed below, the backside metallization is provided in the form of a backslide metallization layer that can provide a radio-frequency (RF) shield and/or a heat dissipation device for the bottom IC. Common elements between the IC package 800 in FIG. 8 and the IC package 100 in FIGS. 1A and 1B are shown with common element numbers.

As shown in FIG. 8, in this example, it is desired to also be able to provide a RF shield and/or a heat dissipation device for the bottom IC 120. In this regard, a backside metallization 848 in the form of a backside metal layer 850 is formed either in contact with or adjacent to the back side 142 of the bottom IC 120 in the vertical direction (Z-axis direction). In this example, the backside metal layer 850 is formed from a metal layer that as disposed on or adjacent to the back side 142 of the bottom IC 120, but does not make electrical contact with circuits inside the bottom IC 120. In this manner, there is a thermal coupling between the backside metal layer 850 and the bottom IC 120 such that heat generated by the bottom IC 120 may be more easily dissipated through the backside metal layer 850. Also, if the bottom IC 120 contains circuits that are sensitive to noise signals, such as RF circuits, the backside metal layer 850 can also provide a RF shield to the bottom IC 120.

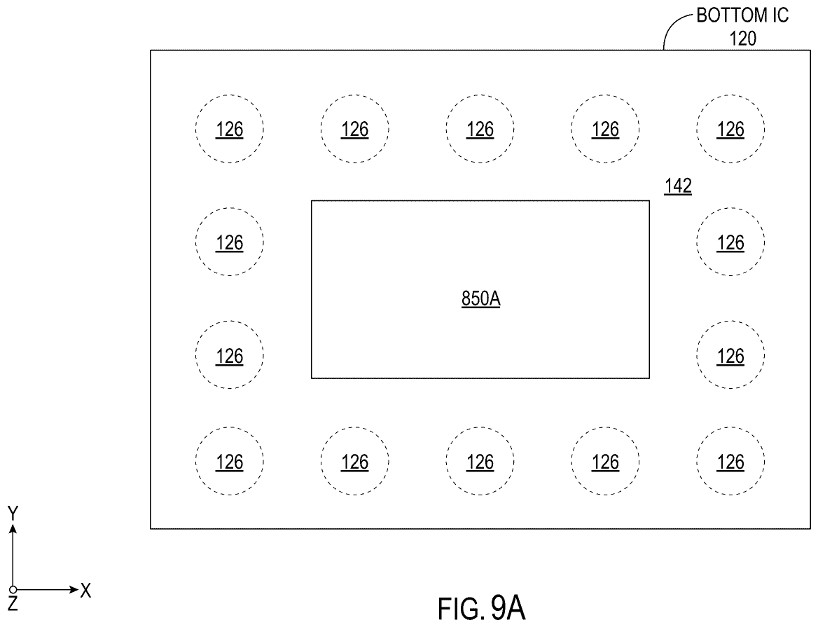

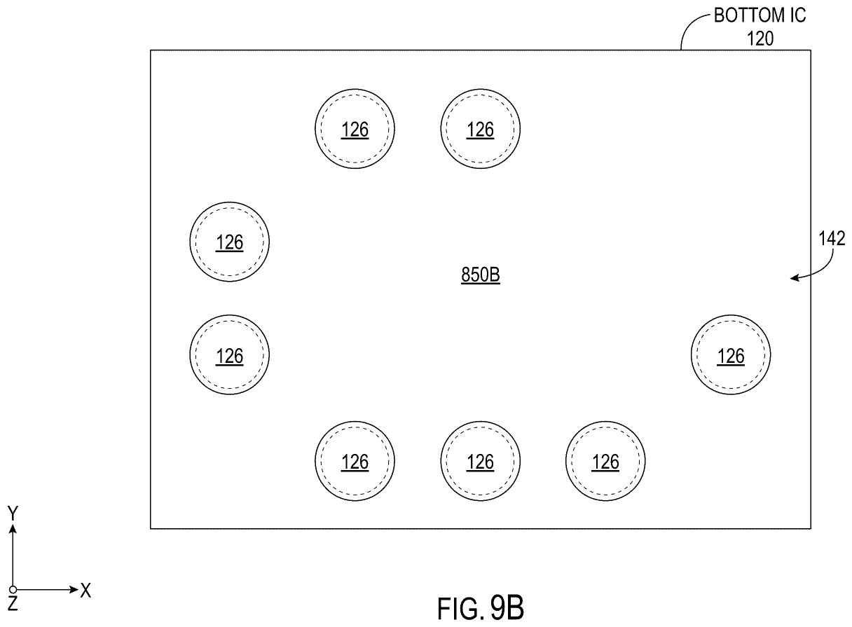

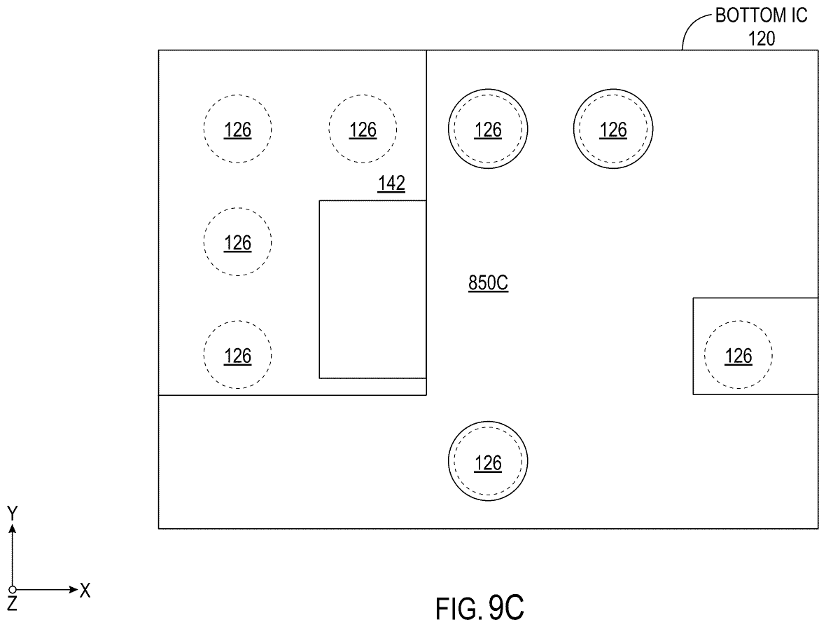

Note that although a single backside metallization layer 850 is shown on or adjacent to the back side 142 of the bottom IC 120 in the IC package 800 in FIG. 8, other alternatives are possible. These are shown as examples in FIGS. 9A-9C that illustrate exemplary bottom views of the bottom IC 120 in the IC package 800 in FIG. 8 with alternative backside metallization layers that can be provided in the IC package 800 in FIG. 8. As shown in FIG. 9A for example, a backside metallization layer 850A is provided that is only partially disposed on or adjacent to the back side 142 of the bottom IC 120. As another example, as shown in FIG. 9B, a backside metallization layer 850B is provided that is fully disposed on or adjacent to the back side 142 of the bottom IC 120. As another example, as shown in FIG. 9C, a backside metallization layer 850C is provided that is partially disposed on or adjacent to the back side 142 of the bottom IC 120. Note that a backside metallization layer can be provided that is comprised of multiple separate metal layers disposed on or adjacent to the back side 142 of the bottom IC 120.

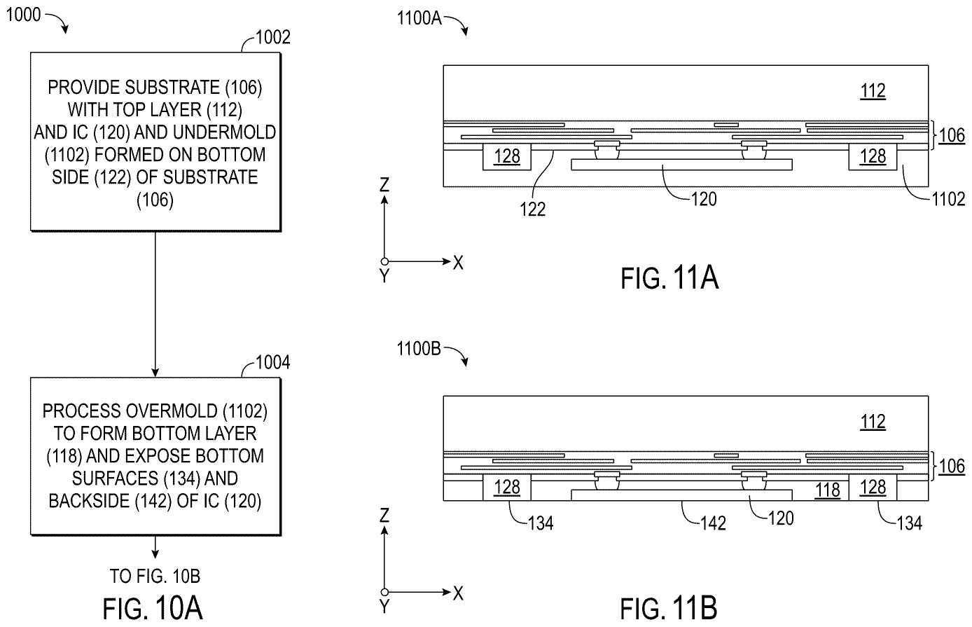

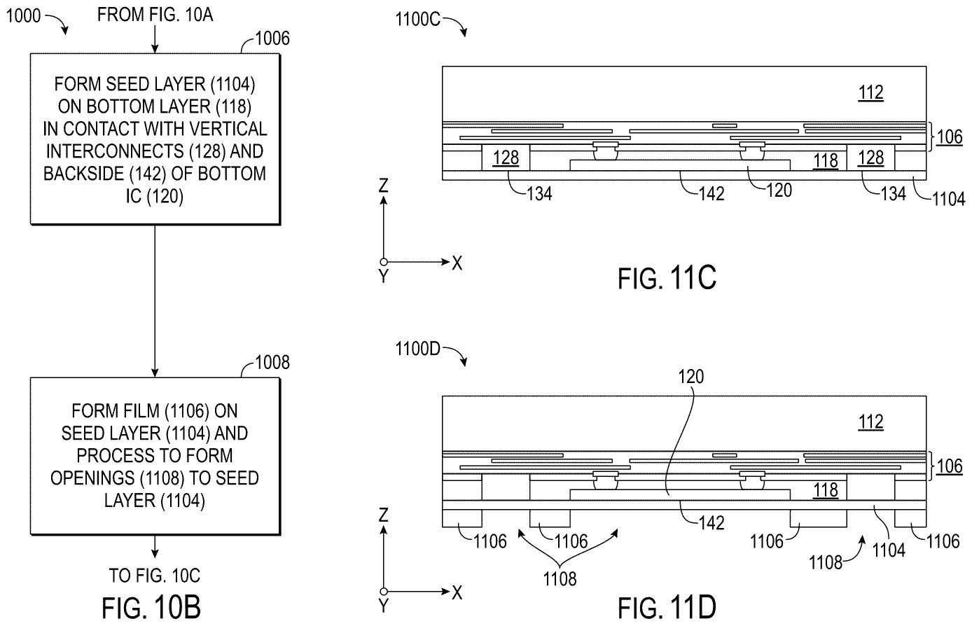

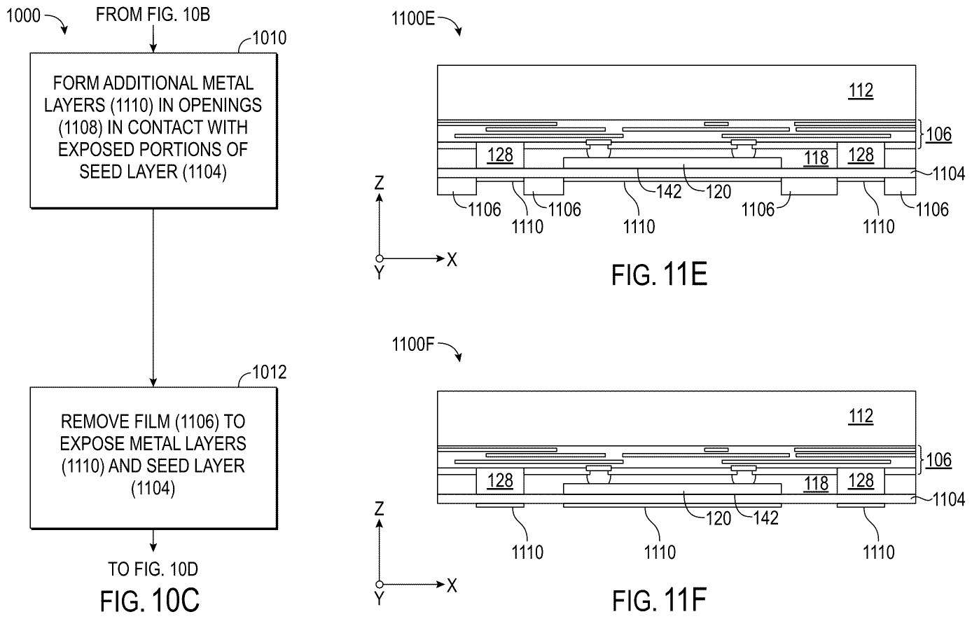

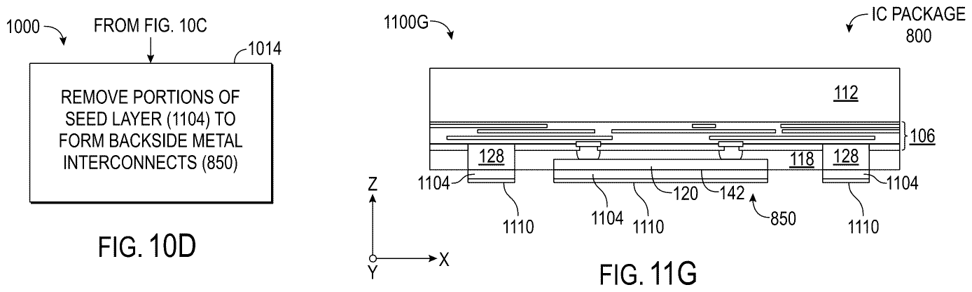

FIGS. 10A-10D is a flowchart illustrating another exemplary process 1000 of fabricating a double-sided IC package that includes a backside metallization for a bottom IC in the form of a backside metal layer to provide direct external connections to the bottom IC, including, but not limited to, the IC package 800 in FIG. 8. FIGS. 11A-11G are exemplary fabrication stages 1100A-1100G during fabrication of the double-sided IC package according to the exemplary fabrication process 1000 in FIGS. 10A-10D. The exemplary process 1000 in FIGS. 10A-10D will be discussed in reference to the IC package 800 in FIG. 8, but such is not limiting.

In this regard, as shown in the exemplary fabrication stage 1100A in FIG. 11A, a first fabrication step can be to provide the substrate 106 with the top layer 112 disposed thereon (block 1002 in FIG. 10A). The vertical interconnects 128 have been formed in the bottom layer 118. An overmold 1102 of a molding compound is disposed on the bottom side 122 of the substrate 106 and encapsulates the vertical interconnects 128. This is to prepare the bottom layer 118 to be formed on the bottom side 122 of the substrate 106. Then, as shown in the exemplary fabrication stage 1100B in FIG. 11B, the overmold 1102 is processed, by removing or grinding down the overmold 1102 to form the final bottom layer 118 for the IC package 800 (block 1004 in FIG. 10A). This process may also involve grinding down of the vertical interconnects 128 to form the bottom surfaces 134 of the vertical interconnects 128 to be planar or substantially planar with the back side 142 of the bottom IC 120.

Then, as shown in the exemplary fabrication stage 1100C in FIG. 11C, a next step in the fabrication process 1000 is to form a seed layer 1104 on the bottom layer 118 and in contact with the bottom surfaces 134 of the vertical interconnects 128 and the back side 142 of the bottom IC 120 (block 1006 in FIG. 10B). The seed layer 1104 may be formed on the bottom layer 118 by a sputtering process. The seed layer 1104 is a conductive material that is intended to provide a good material bond to the bottom surfaces 134 of the vertical interconnects 128 to improve conductivity. Then, as shown in the exemplary fabrication stage 1100D in FIG. 11D, a next step in the fabrication process 1000 can be to deposit a film 1106 on the seed layer 1104 and to process the film 1106 to pattern the film 1106 as a patterning layer (e.g., by an exposure and etch process), to create openings 1108 that extend to the seed layer 1104 adjacent to the bottom surfaces 134 of the vertical interconnects 128 and the back side 142 of the bottom IC 120 (block 1008 in FIG. 10B). Then, as shown in exemplary fabrication stage 1100E in FIG. 11E, a next step in the fabrication process 1000 can be to form additional metal layers 1110 in the openings 1108 and in contact with the exposed portions of the seed layer 1104 (block 1010 in FIG. 10C). This step can be performed for example by an electroless plating process. In this manner, the additional metal layers 1110 that are added to the vertical interconnects 128 and back side 142 of the bottom IC 120 for the backside metal layer 850 can be formed in the same process step.

Then, as shown in the exemplary fabrication stage 1100F in FIG. 11F, a next step in the fabrication process 1000 can be to remove the film 1106 to expose just the additional metal layers 1110 (block 1012 in FIG. 10C). Then, as shown in the exemplary fabrication stage 1100G in FIG. 11G, a next step in the fabrication process 1000 can be to remove the portions of the seed layer 1104 that are outside of the additional metal layers 1110 (block 1014 in FIG. 10D). After this step, the combination of the additional metal layer 1110 and remnant seed layer 1104 on or adjacent to the back side 142 of the bottom IC 120 forms the backside metal layer 850. The creates the IC package 800 with the backside metal layer 850 formed on or adjacent to the back side 142 of the bottom IC 120.

Alternatively, an electroless plating process could be employed to form the backside metallization layer 850 in the IC package 800 in FIG. 11G. In this regard, the seed layer 1104 would not be disposed on the bottom layer 118 and in contact with the exposed bottom surfaces 134 of the vertical interconnects 128 and back side 142 of the bottom IC 120, as shown in FIG. 11B. Alternatively, an electroless plating could be performed on the exposed bottom surfaces 134 of the vertical interconnects 128 and back side 142 of the bottom IC 120 to build up metal layers thereon. In this regard, what constitutes the additional metal layers from the seed layer 1104 and additional metal layers 1110 in the IC package 800 in FIG. 11G could be formed by depositing metal material on the exposed bottom surfaces 134 of the vertical interconnects 128 and the back side 142 of the bottom IC 120. For example, the process can include pretreatment of the exposed bottom surfaces 134 of the vertical interconnects 128 and back side 142 of the bottom IC 120 to clean their surfaces to remove contaminants, sensitization of the exposed bottom surfaces 134 of the vertical interconnects 128 and back side 142 of the bottom IC 120 to reduce the active metal to serve as a catalytic site for the templation of the active metal, activation of the sensitized exposed bottom surfaces 134 of the vertical interconnects 128 back side 142 of the bottom IC 120 with metal nanoparticles (e.g., silver, gold, palladium) to accelerate deposition of additional metal material by acting as a catalytic seed, and then an electroless deposition of metal material thereon.

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

IC packages that include a substrate with top and bottom layers encapsulating respective top and bottom electrical components coupled to respective top and bottom sides of the substrate, and wherein the IC package includes a backside metallization for a bottom IC, including, but not limited to, the IC packages 100, 300, 400, 800, 900A, 900B, 900C in FIGS. 1A-1B, 3, 4, 7G, 8, 9, and 11G, and that can be fabricated according to a fabrication process, including, but not limited to, the fabrication processes 500, 600, 1000 in FIGS. 5, 6A-6D, and 10A-10D, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

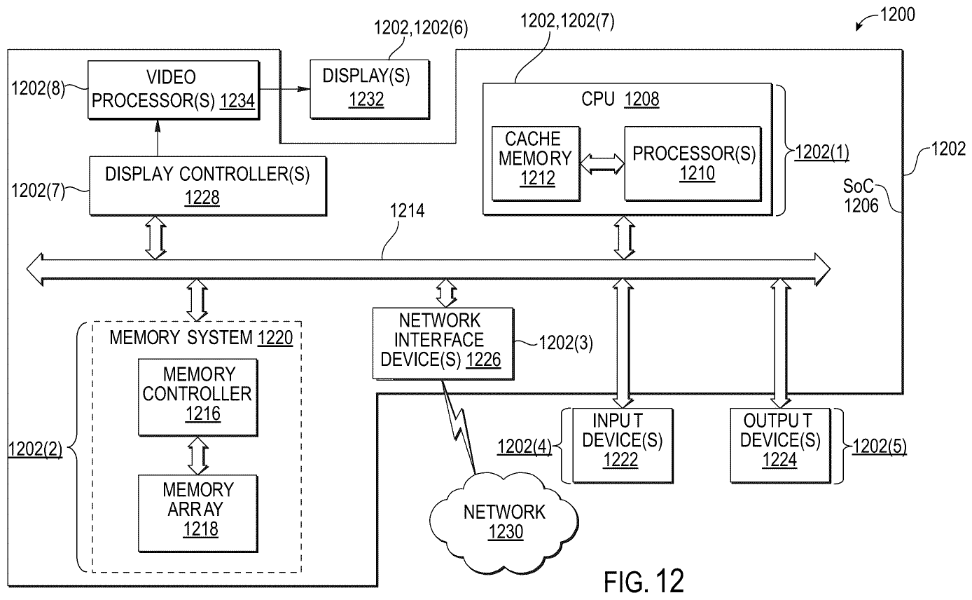

In this regard, FIG. 12 illustrates an example of a processor-based system 1200 that includes one or more IC packages 1202, 1202(1)-1202(8), including, but not limited to, the IC packages 100, 300, 400, 800, 900A, 900B, 900C in FIGS. 1A-1B, 3, 4, 7G, 8, 9, and 11G, that include a substrate with top and bottom layers encapsulating respective top and bottom electrical components coupled to respective top and bottom sides of the substrate, and wherein the IC package includes a backside metallization for a bottom IC. The IC packages 1202, 1202(1)-1202(8) can be fabricated according to a fabrication process, including, but not limited to, the exemplary fabrication processes 500, 600, 1000 in FIGS. 5, 6A-6D, and 10A-10D, and according to any aspects disclosed herein.

In this example, the processor-based system 1200 may be provided in the IC package 1202, such as a system-on-a-chip (SoC) 1206. The processor-based system 1200 includes a CPU 1208 that includes one or more processors 1210, which may also be referred to as CPU cores or processor cores. The CPU 1208 can be provided in an IC package 1202(1). The CPU 1208 may have cache memory 1212 coupled to the CPU 1208 for rapid access to temporarily stored data. The CPU 1208 is coupled to a system bus 1214 and can intercouple master and slave devices included in the processor-based system 1200. As is well known, the CPU 1208 communicates with these other devices by exchanging address, control, and data information over the system bus 1214. For example, the CPU 1208 can communicate bus transaction requests to a memory controller 1216 as an example of a slave device. Although not illustrated in FIG. 12, multiple system buses 1214 could be provided, wherein each system bus 1214 constitutes a different fabric.

Other master and slave devices can be connected to the system bus 1214. As illustrated in FIG. 12, these devices can include a memory system 1220 that includes the memory controller 1216 and a memory array(s) 1218, one or more input devices 1222, one or more output devices 1224, one or more network interface devices 1226, and one or more display controllers 1228, as examples. The memory system 1220 can be provided in an IC package 1202(2). The network interface devices 1226 can be provided in an IC package 1202(3). Each of the memory system 1220, the one or more input devices 1222, the one or more output devices 1224, the one or more network interface devices 1226, and the one or more display controllers 1228 can be provided in the same or different circuit packages. The input devices 1222 and/or the output devices 1224 can be provided in a respective IC package 1202(4), 1202(5). The input device(s) 1222 can include any type of input device, including, but not limited to, input keys, switches, voice processors, etc. The output device(s) 1224 can include any type of output device, including, but not limited to, audio, video, other visual indicators, etc. The network interface device(s) 1226 can be any device configured to allow exchange of data to and from a network 1230. The network 1230 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1226 can be configured to support any type of communications protocol desired.

The CPU 1208 may also be configured to access the display controller(s) 1228 over the system bus 1214 to control information sent to one or more displays 1232. The display(s) 1232 can be provided in an IC package 1202(6). The display controller(s) 1228 sends information to the display(s) 1232 to be displayed via one or more video processors 1234, which process the information to be displayed into a format suitable for the display(s) 1232. The display controller(s) 1228 and video processor(s) 1234 can be provided in a respective IC package 1202(7), 1202(8), or be provided in the same IC package 1202, or be provided in the same IC package 1202(1) containing the CPU 1208 as an example. The display(s) 1232 can include any type of display, including, but not limited to, a cathode ray tube (CRT), a liquid crystal display (LCD), a plasma display, a light emitting diode (LED) display, etc.

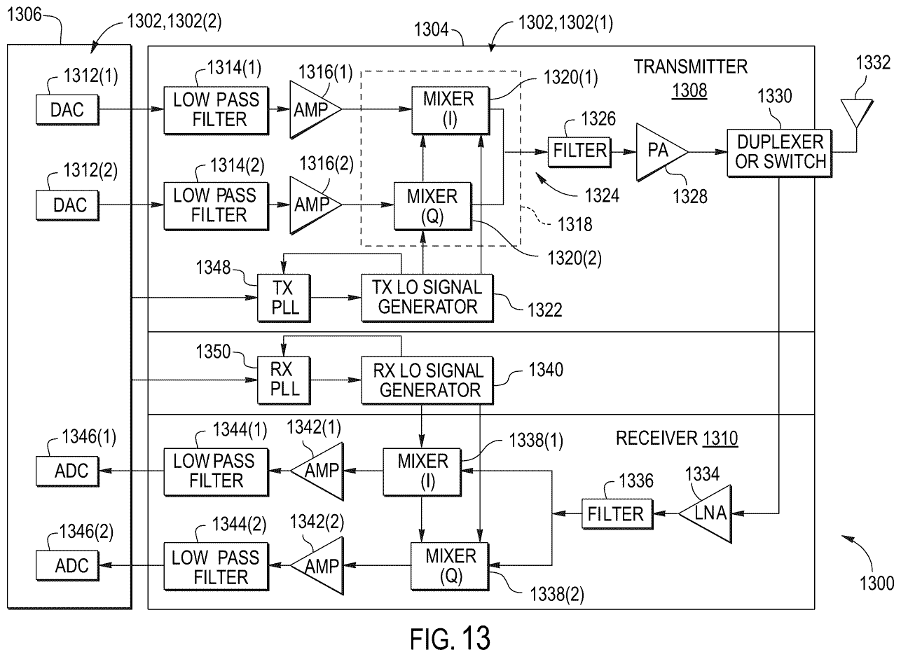

In this regard, FIG. 13 illustrates an exemplary wireless communications device 1300 that includes one or more IC packages 1302, 1302(1)-1302(2) including, but not limited to, the IC packages 100, 300, 400, 800, 900A, 900B, 900C in FIGS. 1A-1B, 3, 4, 7G, 8, 9, and 11G, that include a substrate with top and bottom layers encapsulating respective top and bottom electrical components coupled to respective top and bottom sides of the substrate, and wherein the IC package includes a backside metallization for a bottom IC. The IC packages 1302, 1302(1)-1302(2) can be fabricated according to a fabrication process, including, but not limited to, the exemplary fabrication processes 500, 600, 1000 in FIGS. 5, 6A-6D, and 10A-10D, and according to any aspects disclosed herein.

The wireless communications device 1300 may include or be provided in any of the above-referenced devices, as examples. As shown in FIG. 13, the wireless communications device 1300 includes a transceiver 1304 and a data processor 1306. The data processor 1306 may include a memory to store data and program codes. The transceiver 1304 includes a transmitter 1308 and a receiver 1310 that support bi-directional communications. In general, the wireless communications device 1300 may include any number of transmitters 1308 and/or receivers 1310 for any number of communication systems and frequency bands. All or a portion of the transceiver 1304 may be implemented on one or more analog ICs, RF ICs (RFICs), mixed-signal ICs, etc.

The transmitter 1308 or the receiver 1310 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1310. In the direct-conversion architecture, a signal is frequency-converted between RF and baseband in one stage. The super-heterodyne and direct-conversion architectures may use different circuit blocks and/or have different requirements. In the wireless communications device 1300 in FIG. 13, the transmitter 1308 and the receiver 1310 are implemented with the direct-conversion architecture.

In the transmit path, the data processor 1306 processes data to be transmitted and provides I and Q analog output signals to the transmitter 1308. In the exemplary wireless communications device 1300, the data processor 1306 includes digital-to-analog converters (DACs) 1312(1), 1312(2) for converting digital signals generated by the data processor 1306 into the I and Q analog output signals, e.g., I and Q output currents, for further processing.

Within the transmitter 1308, lowpass filters 1314(1), 1314(2) filter the I and Q analog output signals, respectively, to remove undesired signals caused by the prior digital-to-analog conversion. Amplifiers (AMPs) 1316(1), 1316(2) amplify the signals from the lowpass filters 1314(1), 1314(2), respectively, and provide I and Q baseband signals. An upconverter 1318 upconverts the I and Q baseband signals with I and Q transmit (TX) local oscillator (LO) signals through mixers 1320(1), 1320(2) from a TX LO signal generator 1322 to provide an upconverted signal 1324. A filter 1326 filters the upconverted signal 1324 to remove undesired signals caused by the frequency upconversion as well as noise in a receive frequency band. A power amplifier (PA) 1328 amplifies the upconverted signal 1324 from the filter 1326 to obtain the desired output power level and provides a transmit RF signal. The transmit RF signal is routed through a duplexer or switch 1330 and transmitted via an antenna 1332.

In the receive path, the antenna 1332 receives signals transmitted by base stations and provides a received RF signal, which is routed through the duplexer or switch 1330 and provided to a low noise amplifier (LNA) 1334. The duplexer or switch 1330 is designed to operate with a specific receive (RX)-to-TX duplexer frequency separation, such that RX signals are isolated from TX signals. The received RF signal is amplified by the LNA 1334 and filtered by a filter 1336 to obtain a desired RF input signal. Downconversion mixers 1338(1), 1338(2) mix the output of the filter 1336 with I and Q RX LO signals (i.e., LO_I and LO_Q) from an RX LO signal generator 1340 to generate I and Q baseband signals. The I and Q baseband signals are amplified by AMPs 1342(1), 1342(2) and further filtered by lowpass filters 1344(1), 1344(2) to obtain I and Q analog input signals, which are provided to the data processor 1306. In this example, the data processor 1306 includes analog-to-digital converters (ADCs) 1346(1), 1346(2) for converting the analog input signals into digital signals to be further processed by the data processor 1306.

In the wireless communications device 1300 of FIG. 13, the TX LO signal generator 1322 generates the I and Q TX LO signals used for frequency upconversion, while the RX LO signal generator 1340 generates the I and Q RX LO signals used for frequency downconversion. Each LO signal is a periodic signal with a particular fundamental frequency. A TX phase-locked loop (PLL) circuit 1348 receives timing information from the data processor 1306 and generates a control signal used to adjust the frequency and/or phase of the TX LO signals from the TX LO signal generator 1322. Similarly, an RX PLL circuit 1350 receives timing information from the data processor 1306 and generates a control signal used to adjust the frequency and/or phase of the RX LO signals from the RX LO signal generator 1340.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. An integrated circuit (IC) package, comprising:
a substrate comprising a top side and a bottom side opposite the top side;
a top layer adjacent to the top side of the substrate, the top layer comprising:
   an electrical component electrically coupled to the top side of the substrate;
a bottom layer adjacent to the bottom side of the substrate, the bottom layer comprising:
   a bottom IC, comprising:
      a front side adjacent to the substrate and electrically coupled to the substrate; and
      a back side opposite the front side of the bottom IC, the back side exposed from the bottom layer; and
a backside metallization on the back side of the bottom IC.

2. The IC package of clause 1, wherein:
the bottom IC further comprises a plurality of metal pads exposed from the back side of the bottom IC; and
the backside metallization comprises a plurality of backside metal interconnects each coupled to a metal pad of the plurality of metal pads.

3. The IC package of clause 2, wherein the plurality of metal pads is a ball grid array (BGA).

4. The IC package of clause 2 or 3, wherein the plurality of backside metal interconnects comprises a plurality of backside metal layers.

5. The IC package of clause 2 or 3, wherein the plurality of backside metal interconnects comprises a plurality of backside solder balls.

6. The IC package of any of clauses 1-3, wherein the backside metallization comprises one or more backside metallization layers.

7. The IC package of clause 6, wherein the one or more backside metallization layers comprise a single backside metallization layer disposed fully on the back side of the bottom IC.

8. The IC package of clause 6, wherein the one or more backside metallization layers comprise a single backside metallization layer disposed on a portion of the back side of the bottom IC.

9. The IC package of clause 6, wherein the one or more backside metallization layers comprise a plurality of backside metallization layers each disposed on a portion of the back side of the bottom IC.

10. The IC package of any of clauses 1-9, further comprising one or more vertical interconnects each electrically coupled to the substrate and that each extend from the substrate to the bottom layer exposed from the bottom layer;
wherein the bottom IC is electrically coupled to at least one of the one or more vertical interconnects through the substrate.

11. The IC package of clause 10, wherein the one or more vertical interconnects are disposed outside an area of the bottom IC in the bottom layer.

12. The IC package of any of clauses 1-11, wherein:
the substrate comprises one or more metallization layers each comprising a plurality of metal interconnects;
the electrical component is electrically coupled to at least one metal interconnect in the one or more metallization layers of the substrate; and
the front side of the bottom IC is electrically coupled to at least one metal interconnect in the one or more metallization layers of the substrate.

13. The IC package of any of clauses 1-12 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

14. A method of fabricating an integrated circuit (IC) package, comprising:
providing a substrate comprising a top side and a bottom side opposite the top side;
electrically coupling an electrical component to the top side of the substrate;
forming a top layer adjacent to the top side of the substrate, the top layer comprising the electrical component;
electrically coupling a front side of a bottom IC to the substrate;
forming a bottom layer adjacent to the bottom side of the substrate, the bottom layer comprising the bottom IC with a back side of the bottom IC exposed from the bottom layer; and
forming a backside metallization on the back side of the bottom IC.

15. The method of clause 14, wherein:
the bottom IC further comprises a plurality of metal pads exposed from the back side of the bottom IC; and
forming the backside metallization comprises forming a plurality of backside metal interconnects on the back side of the bottom IC each coupled to a metal pad of the plurality of metal pads.

16. The method of clause 14, wherein forming the backside metallization comprises forming one or more backside metallization layers on the back side of the bottom IC.

17. The method of clause 16, wherein forming the bottom layer comprises:
forming an overmold on the bottom IC and adjacent to the bottom side of the substrate; and
removing material from the overmold down to the back side of the bottom IC to form the bottom layer to expose the back side of the bottom IC from the bottom layer.

18. The method of clause 17, wherein forming the backside metallization on the back side of the bottom IC comprises:
forming a seed layer on the back side of the bottom IC; and
forming a metal layer on the seed layer.

19. The method of clause 17, wherein forming the backside metallization on the back side of the bottom IC further comprises:
forming a seed layer on the back side of the bottom IC;
forming a film on the seed layer;
forming one or more openings in the film;
forming a plurality of backside metal interconnects each in an opening of the one or more openings and coupled to the seed layer;
removing the film; and
etching the seed layer outside of the plurality of backside metal interconnects.

20. The method of clause 17, wherein forming the backside metallization on the back side of the bottom IC further comprises:
forming a seed layer on the back side of the bottom IC;
forming a film on the seed layer;
forming an opening in the film;
forming a backside metal layer in the opening and coupled to the seed layer;
removing the film; and
etching the seed layer outside of the backside metal layer.

21. An electronic assembly, comprising:
a circuit board comprising a metallization layer comprising a plurality of metal interconnects;
an integrated circuit (IC) package, comprising:
a substrate comprising a top side and a bottom side opposite the top side;
a top layer adjacent to the top side of the substrate, the top layer comprising:
an electrical component electrically coupled to the top side of the substrate;
a bottom layer adjacent to the bottom side of the substrate, the bottom layer comprising:
a bottom IC, comprising:
a front side adjacent to the substrate and electrically coupled to the substrate;
a back side opposite the front side of the bottom IC, the back side exposed from the bottom layer; and
a plurality of metal pads exposed from the back side of the bottom IC;
a plurality of backside metal interconnects each coupled to a metal pad of the plurality of metal pads of the bottom IC and each coupled to a metal interconnect of the plurality of metal interconnects of the circuit board.

22. The electronic assembly of clause 21, further comprising a plurality of solder balls each interconnecting a backside metal interconnect of the plurality of backside metal interconnects to a metal interconnect of the plurality of metal interconnects of the circuit board.

23. The electronic assembly of clause 21, further comprising a plurality of metal layers each interconnecting a backside metal interconnect of the plurality of backside metal interconnects to a metal interconnect of the plurality of metal interconnects of the circuit board.

What is claimed is:

1. An integrated circuit (IC) package, comprising:
a substrate comprising a top side and a bottom side opposite the top side;
a top layer adjacent to the top side of the substrate, the top layer comprising:
an electrical component electrically coupled to the top side of the substrate;
a bottom layer adjacent to the bottom side of the substrate, the bottom layer comprising:
a bottom IC, comprising:
a front side adjacent to the substrate and electrically coupled to the substrate; and
a back side opposite the front side of the bottom IC, the back side exposed from the bottom layer; and
a backside metallization on the back side of the bottom IC.

2. The IC package of claim 1, wherein:
the bottom IC further comprises a plurality of metal pads exposed from the back side of the bottom IC; and
the backside metallization comprises a plurality of backside metal interconnects each coupled to a metal pad of the plurality of metal pads.

3. The IC package of claim 2, wherein the plurality of metal pads is a ball grid array (BGA).

4. The IC package of claim 2, wherein the plurality of backside metal interconnects comprises a plurality of backside metal layers.

5. The IC package of claim 2, wherein the plurality of backside metal interconnects comprises a plurality of backside solder balls.

6. The IC package of claim 1, wherein the backside metallization comprises one or more backside metallization layers.

7. The IC package of claim 6, wherein the one or more backside metallization layers comprise a single backside metallization layer disposed fully on the back side of the bottom IC.

8. The IC package of claim 6, wherein the one or more backside metallization layers comprise a single backside metallization layer disposed on a portion of the back side of the bottom IC.

9. The IC package of claim 6, wherein the one or more backside metallization layers comprise a plurality of backside metallization layers each disposed on a portion of the back side of the bottom IC.

10. The IC package of claim 1, further comprising one or more vertical interconnects each electrically coupled to the substrate and that each extend from the substrate to the bottom layer exposed from the bottom layer;
wherein the bottom IC is electrically coupled to at least one of the one or more vertical interconnects through the substrate.

11. The IC package of claim 10, wherein the one or more vertical interconnects are disposed outside an area of the bottom IC in the bottom layer.

12. The IC package of claim 1, wherein:
the substrate comprises one or more metallization layers each comprising a plurality of metal interconnects;
the electrical component is electrically coupled to at least one metal interconnect in the one or more metallization layers of the substrate; and
the front side of the bottom IC is electrically coupled to at least one metal interconnect in the one or more metallization layers of the substrate.

13. The IC package of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

14. A method of fabricating an integrated circuit (IC) package, comprising:
providing a substrate comprising a top side and a bottom side opposite the top side;
electrically coupling an electrical component to the top side of the substrate;
forming a top layer adjacent to the top side of the substrate, the top layer comprising the electrical component;
electrically coupling a front side of a bottom IC to the substrate;
forming a bottom layer adjacent to the bottom side of the substrate, the bottom layer comprising the bottom IC with a back side of the bottom IC exposed from the bottom layer; and
forming a backside metallization on the back side of the bottom IC.

15. The method of claim 14, wherein:
the bottom IC further comprises a plurality of metal pads exposed from the back side of the bottom IC; and
forming the backside metallization comprises forming a plurality of backside metal interconnects on the back side of the bottom IC each coupled to a metal pad of the plurality of metal pads.

16. The method of claim 14, wherein forming the backside metallization comprises forming one or more backside metallization layers on the back side of the bottom IC.

17. The method of claim 16, wherein forming the bottom layer comprises:
forming an overmold on the bottom IC and adjacent to the bottom side of the substrate; and
removing material from the overmold down to the back side of the bottom IC to form the bottom layer to expose the back side of the bottom IC from the bottom layer.

18. The method of claim 17, wherein forming the backside metallization on the back side of the bottom IC comprises:
forming a seed layer on the back side of the bottom IC; and
forming a metal layer on the seed layer.

19. The method of claim 17, wherein forming the backside metallization on the back side of the bottom IC further comprises:
forming a seed layer on the back side of the bottom IC;
forming a film on the seed layer;
forming one or more openings in the film;
forming a plurality of backside metal interconnects each in an opening of the one or more openings and coupled to the seed layer;
removing the film; and
etching the seed layer outside of the plurality of backside metal interconnects.

20. The method of claim 17, wherein forming the backside metallization on the back side of the bottom IC further comprises:
forming a seed layer on the back side of the bottom IC;
forming a film on the seed layer;
forming an opening in the film;
forming a backside metal layer in the opening and coupled to the seed layer;
removing the film; and
etching the seed layer outside of the backside metal layer.

21. An electronic assembly, comprising:
a circuit board comprising a metallization layer comprising a plurality of metal interconnects;
an integrated circuit (IC) package, comprising:
a substrate comprising a top side and a bottom side opposite the top side;
a top layer adjacent to the top side of the substrate, the top layer comprising:
an electrical component electrically coupled to the top side of the substrate;
a bottom layer adjacent to the bottom side of the substrate, the bottom layer comprising:
a bottom IC, comprising:
a front side adjacent to the substrate and electrically coupled to the substrate;
a back side opposite the front side of the bottom IC, the back side exposed from the bottom layer; and
a plurality of metal pads exposed from the back side of the bottom IC;
a plurality of backside metal interconnects each coupled to a metal pad of the plurality of metal pads of the bottom IC and each coupled to a metal interconnect of the plurality of metal interconnects of the circuit board.

22. The electronic assembly of claim 21, further comprising a plurality of solder balls each interconnecting a backside metal interconnect of the plurality of backside metal interconnects to a metal interconnect of the plurality of metal interconnects of the circuit board.

23. The electronic assembly of claim 21, further comprising a plurality of metal layers each interconnecting a backside metal interconnect of the plurality of backside metal interconnects to a metal interconnect of the plurality of metal interconnects of the circuit board.
